(19) United States
(12) Patent Application Publication
(10) Pub. No.: US 2025/0125235 A1
(43) Pub. Date: Apr. 17, 2025

(54) SEMICONDUCTOR DEVICE WITH MULTI-ALLOY BALL GRID ARRAY

(71) Applicant: Micron Technology, Inc., Boise, ID (US)

(72) Inventor: Steve D. ABRAHAMSON, Boise, ID (US)

(21) Appl. No.: 18/790,383

(22) Filed: Jul. 31, 2024

Related U.S. Application Data
(60) Provisional application No. 63/589,420, filed on Oct. 11, 2023.

(51) Int. Cl. H01L 23/498; H01L 21/48; H01L 23/00; H01L 23/31; H01L 23/538; H01L 25/18

(52) U.S. Cl. CPC H01L 23/49816; H01L 21/4853; H01L 23/5383; H01L 23/562; H01L 23/3107; H01L 25/18

(57) ABSTRACT

A semiconductor device assembly includes a circuit substrate comprising a first substrate surface and a second substrate surface arranged opposite to the first substrate surface; at least one die arranged on the first substrate surface; a package casing disposed over the first substrate surface, wherein the package casing encapsulates the at least one die and covers at least part of the first substrate surface; and a multi-alloy ball grid array coupled to the second substrate surface. The multi-alloy ball grid array includes a first plurality of solder balls made of a first solder alloy and a second plurality of solder balls made of a second solder alloy that is different from the first solder alloy.

### CROSS REFERENCE TO RELATED APPLICATION

This Patent Application claims priority to U.S. Provisional Patent Application No. 63/589,420, filed on Oct. 11, 2023, and entitled “SEMICONDUCTOR DEVICE WITH MULTI-ALLOY BALL GRID ARRAY.” The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to semiconductor devices having a multi-alloy ball grid array.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as by balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components by the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of a ball side of a semiconductor package assembly according to one or more implementations.

FIG. 3 is a diagram of a ball side of a semiconductor package assembly according to one or more implementations.

FIG. 4 is a flowchart of an example method of forming a semiconductor device assembly or memory device having a multi-alloy ball grid array.

### DETAILED DESCRIPTION

A semiconductor package assembly may be one type of semiconductor device assembly that is structured to house one or more dies. Typically, one or more dies are attached to a die side of a circuit substrate, and a package casing, such as a molded compound casing, is disposed over the die side of the circuit substrate to encapsulate the one or more dies. Conductive interconnect structures, such as solder balls, may be attached to a back-side of the circuit substate to provide electrical connections to the one or more dies.

Solder balls (e.g., solder balls of a ball grid array (BGA)) are vulnerable to a number of issues as a result of stresses present at the circuit substrate to which the solder balls are attached. For example, the circuit substrate may warp either during production or during a lifetime of the semiconductor package. Warpage may cause solder joint failures at the solder balls.

Alternatively, or additionally, a defect referred to as “head-in-pillow” may form during production. A head-in-pillow defect is a failure of the soldering process caused by an incomplete wetting of the entire solder joint of a BGA, chip-scale package (CSP), or even a package-on-package (PoP), and is characterized as a process anomaly, where a solder paste and a solder ball both reflow but do not coalesce. One cause of head-in-pillow defects is where a balled semiconductor device is in a reflow oven to be soldered to a printed circuit board (PCB) and the circuit substrate undergoes warpage. For example, the semiconductor package may warp as an x-dimension and a y-dimension of the semiconductor package increases due to exposure to temperatures exceeding 150° C. during a reflow process. During warping, corners of the semiconductor package warp up prior to ball reflow. As a result, solder balls can lift out of the solder paste that is used to create a bond with the PCB. When the solder balls hit reflow, the semiconductor package collapses slightly as the solder balls become molten and a ball shape is taken over by a surface tension of a solder alloy of the solder balls. Often corner solder balls will come back into contact with molten solder paste on the PCB pads. However, during a time when the corner solder balls are lifted out of contact with the solder paste, a solder oxide (e.g., a tin oxide) of the solder paste may float to the top of the solder paste and create a barrier that prevents the solder balls from bonding with or otherwise coalescing with the molten solder paste. In other words, a thin layer of solder oxide prevents intermetallic bonding between the solder balls and the solder paste. Instead, the molten solder paste conforms to a shape of the solder ball without actually bonding to the solder ball. As a result, head-in-pillow defects are incredibly difficult to detect since it appears the solder balls have bonded with the solder from the solder paste, when the solder balls actually have not. Head-in-pillow defects may result in intermittent connections that may pass during a production test, but fail out in the field, which again speaks to the difficulty of detecting head-in-pillow defects.

Moreover, coplanarity of electronic components such as surface mounted devices and connectors is defined as a maximum value of a difference between a highest point and lowest point among multiple conductive interconnect structures (e.g., solder balls of a BGA). The larger the difference between the highest point and the lowest point among the multiple conductive interconnect structures, the larger the coplanarity is for the multiple conductive interconnect structures. Meanwhile, the smaller the difference is between the highest point and the lowest point among the multiple conductive interconnect structures, the smaller the coplanarity is for the multiple conductive interconnect structures. An increase in coplanarity can lead to a gap between one or more conductive interconnect structures and the PCB. Any gap that exceeds an allowable range (e.g., tolerance) can cause problems, such as connection failures of electronic devices mounted on boards, contact failures of connectors, or connection failures caused by even a slight load during use. In addition, an increase in coplanarity during the reflow process may cause the head-in-pillow defects described above. Therefore, mitigating coplanarity can reduce or prevent connection and contact failures from occurring.

The package casing formed on the die side of a circuit substrate may cause the coplanarity to increase. For example, the package casing may shrink at lower temperatures and expand at higher temperatures. The package casing and the circuit substrate may have different coefficients of thermal expansion (e.g., a mismatch in coefficients of thermal expansion). As a result of the mismatch in coefficients of thermal expansion, the package casing and the circuit substrate may shrink or expand by different amounts. As the package casing shrinks by a different amount compared to a shrinking of the circuit substrate, the package casing may induce a mechanical stress in the circuit substrate. The mechanical stress may cause the circuit substrate to bend or warp. For example, as the package casing shrinks, a ratio between the circuit substrate and the package casing may become unbalanced (e.g., due to a mismatch in coefficients of thermal expansion of the circuit substrate and the package casing). The ratio imbalance may cause a coplanarity of the conductive interconnect structures to increase due to warpage of the circuit substrate caused by the change in ratio. The induced mechanical stress may be more prevalent at certain temperatures due to the mismatch in the coefficients of thermal expansion.

In some cases, the warpage of the circuit substrate may occur at or near the edges of the circuit substrate, in a peripheral region of the back-side of the circuit substrate, causing the contact points of some of the conductive interconnect structures closest to the peripheral region to shift relative to conductive interconnect structures located further away from the peripheral region. This shift may cause the coplanarity of the conductive interconnect structures to increase.

In some implementations, a semiconductor device assembly may include a multi-alloy ball grid array coupled to a back-side of a circuit substrate of the semiconductor device assembly. The semiconductor device assembly may be a semiconductor chip package. The multi-alloy ball grid array may include two or more sets of solder balls, with each set being made of a different solder alloy. For example, the multi-alloy ball grid array may include a first plurality of solder balls made of a first solder alloy and a second plurality of solder balls made of a second solder alloy that is different from the first solder alloy. The first plurality of solder balls and the second plurality of solder balls may be electrically coupled to (e.g., have a conductive connection with) at least one die by the circuit substrate.

The circuit substrate may include high-stress areas at which a mechanical stress of the circuit substrate satisfies a stress threshold (e.g., is greater than or equal to, or greater than, the stress threshold) and low-stress areas at which the mechanical stress of the circuit substrate does not satisfy the stress threshold (e.g., is less than or equal to, or less than, the stress threshold). For example, the high-stress areas may be more susceptible to failure (e.g., solder joint failure, head-in-pillow defects, or ball breaks) than the low-stress areas. Thus, the high-stress areas may represent weaker regions of the semiconductor device assembly and the low-stress areas may represent stronger regions of the semiconductor device assembly. The first plurality of solder balls may be arranged at the high-stress areas and the second plurality of solder balls may be arranged at the low-stress areas. In addition, the first solder alloy may have at least one of a higher melting point or a higher stiffness coefficient than the second solder alloy. As a result of using different alloys and positioning the first solder alloy at the high-stress areas and the second solder alloy at the low-stress areas, a warpage of the circuit substrate can be reduced. For example, the warpage of the circuit substrate can be reduced during the reflow process, which may prevent or reduce an occurrence of head-in-pillow defects.

For example, the first plurality of solder balls may be exterior solder balls arranged around a periphery (e.g., an edge region) of the circuit substrate, whereas the second plurality of solder balls may be interior solder balls arranged at an interior region of the circuit substate and surrounded by the exterior solder balls. A solder paste and the exterior solder balls may be made of a tin-based solder alloy (e.g., reflow point around 220° C.), and the interior solder balls may be made of a solder alloy that is near eutectic 57% bismuth, 1% silver, and 42% tin, with a reflow point around 145° C. As a result, the interior solder balls will liquify first, and the semiconductor device assembly is then supported by the exterior solder balls until the exterior solder balls reflow at 220° C. However, if package corners and edges of the semiconductor device assembly begin to warp up prior to 220° C., as the package corners and edges tend to do, the package corners and edges will be pulled down by a surface tension of the melted interior solder balls. Thus, the interior solder balls that have melted sooner than the exterior solder balls may prevent the exterior solder balls located at the package corners and edges from lifting out of the solder paste. In other words, the interior solder balls may reduce warpage and coplanarity during the reflow process and, consequently, reduce or prevent connection and contact failures, such as head-in-pillow defects, from occurring. Hot shorting defects may also be reduced or eliminated by using the multi-alloy ball grid array.

In some implementations, solder balls arranged in the corners of the circuit substrate (e.g., at a corner ball joint) may be dummy solder balls with no electrical connection to a die. The dummy solder balls may be configured to hold a large amount of the mechanical stress and protect neighboring solder balls with an electrical connection to a die from breaking. The dummy solder balls may be made of a solder alloy that is more ductile than a solder alloy used for the neighboring solder balls that have an electrical connection to a die. For example, the solder alloy used for the dummy solder balls may have a lower melting point and/or a lower stiffness coefficient than the solder alloy used for the neighboring solder balls that have an electrical connection to a die. In addition, inner solder balls may also be made of the same solder alloy used for the neighboring solder balls that have an electrical connection to a die. As a result, Rather than most or all of the mechanical forces being focused on the corner ball joint-the ductility of these balls allows some “give” to the stresses, and thus the forces may be shared between the more ductile dummy solder balls at the corners, and the harder solder balls located inwards from the corners (e.g., toward the middle of the circuit substrate).

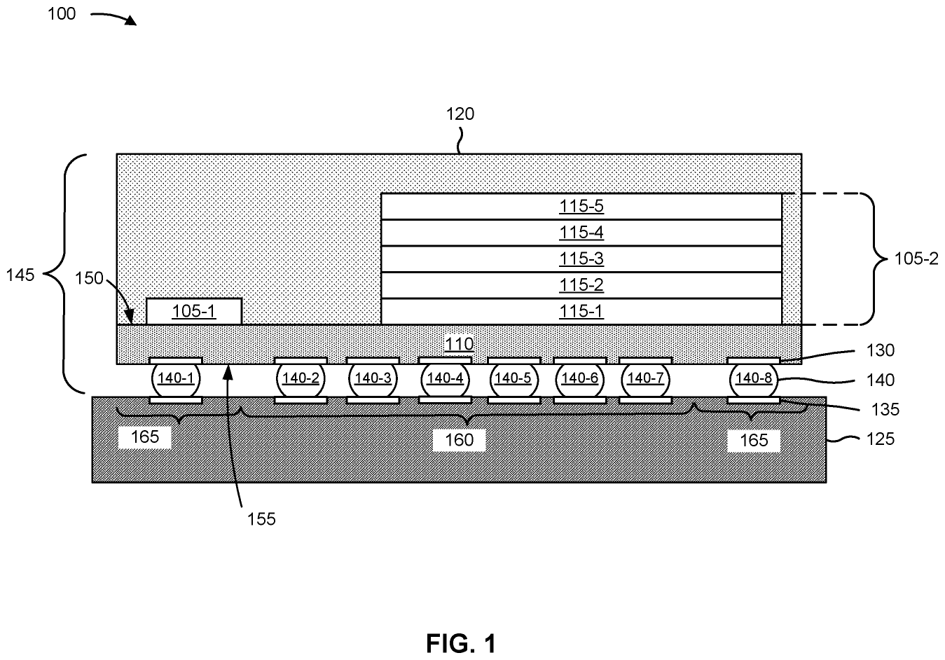

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110 (e.g., a circuit substrate, a substrate interposer, or a conductive interconnect substrate). An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher-level system (e.g., a computer, a mobile phone, a network device, an SSD, a vehicle, or an Internet of Things device), such as by electrically connecting the apparatus 100 to a circuit board 125, such as a PCB. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140-1 to 140-8 (e.g., arranged in a BGA), which may be melted to form a physical and electrical connection between the substrate 110 and the circuit board 125. The solder balls 140-1 to 140-8 may be collectively referred to as solder balls 140. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The substrate 110 may include interconnections that electrically couple the integrated circuits 105 to the solder balls 140. The interconnections between an integrated circuit 105, the substrate 110, and the circuit board 125 enable the integrated circuit 105 to receive and transmit signals to other components of the apparatus 100 and/or the higher-level system.

The substrate 110, the integrated circuits 105, the casing 120, and the electrical contacts 130, and the solder balls 140 may form a semiconductor package assembly 145 that is coupled to the circuit board 125. The semiconductor package assembly 145 may be a semiconductor package or a BGA component package. A surface of the substrate 110 on which the integrated circuits 105 are disposed may be referred to as a first substrate surface 150 (e.g., arranged at a die side or a front side of the substrate 110). A surface of the substrate 110 to which the solder balls 140 are attached may be referred to as a second substrate surface 155 (e.g., arranged at a ball side or a back side of the substrate 110). Thus, the casing 120 may be disposed over the first substrate surface 150 in order to encapsulate the integrated circuits 105 and cover at least part of the first substrate surface 150.

As the casing 120 shrinks or expands relative to the substrate 110, the casing 120 may induce a mechanical stress in the substrate 110 that may cause the substrate 110 to bend or warp. As a result of the mechanical stress and the warpage occurrent from the mechanical stress, a coplanarity of the solder balls 140 may increase. To counterbalance the mechanical stress and the warpage, the solder balls 140 may be part of a multi-alloy BGA.

The second substrate surface 155 of the substrate 110 may include an inner region 160 and a peripheral region 165 that surrounds the inner region 160. For example, the peripheral region 165 may be an exterior region of the second substrate surface 155 that is adjacent to a plurality of exterior edges of the second substrate surface 155 that define the total area of the second substrate surface 155. In other words, the peripheral region 165 may correspond to an edge region of the second substrate surface 155, and the inner region 160 may correspond to an interior region of the second substrate surface 155. The edge region may encircle the interior region.

The multi-alloy ball grid array may include two or more sets of solder balls, with each set being made of a different solder alloy. For example, the multi-alloy ball grid array may include a first plurality of solder balls made of a first solder alloy and a second plurality of solder balls made of a second solder alloy that is different from the first solder alloy.

The substrate 110 may include high-stress areas at which a mechanical stress of the circuit substrate satisfies a stress threshold and low-stress areas at which the mechanical stress of the circuit substrate does not satisfy the stress threshold. For example, the peripheral region 165 may be a high-stress area or may include one or more high-stress areas. In contrast, the inner region 160 may be a low-stress area or may include one or more low-stress areas. The high-stress areas may be more susceptible to failure (e.g., solder joint failure, head-in-pillow defects, or ball breaks) than the low-stress areas. Thus, the high-stress areas may represent weaker regions of the substrate 110 and the low-stress areas may represent stronger regions of the substrate 110.

The first plurality of solder balls may be arranged at the high-stress areas (e.g., in the peripheral region 165) and the second plurality of solder balls may be arranged at the low-stress areas (e.g., in the inner region 160). For example, solder ball 140-1 may be arranged at first high-stress area and solder ball 140-8 may be arranged at second high-stress area. Additionally, solder balls 140-2 to 140-7 may be arranged at different low-stress areas, respectively. Thus, the first plurality of solder balls may include solder balls 140-1 and 140-8, whereas the second plurality of solder balls may include solder balls 140-2 to 140-7.

The first solder alloy of the first plurality of solder balls may have at least one of a higher melting point or a higher stiffness coefficient than the second solder alloy of the second plurality of solder balls. For example, a first melting point of the first solder alloy may be at least 10% greater than a second melting point of the second solder alloy. Alternatively, or additionally, a first stiffness coefficient of the first solder alloy may be at least 10% greater than a second stiffness coefficient of the second solder alloy. In some implementations, a first melting point of the first solder alloy may be at least 5% greater than a second melting point of the second solder alloy. Alternatively, or additionally, a first stiffness coefficient of the first solder alloy may be at least 5% greater than a second stiffness coefficient of the second solder alloy. In some implementations, a first melting point of the first solder alloy may be at least 15% greater than a second melting point of the second solder alloy. Alternatively, or additionally, a first stiffness coefficient of the first solder alloy may be at least 15% greater than a second stiffness coefficient of the second solder alloy. In some implementations, the first solder alloy may be SAC305 (e.g., 96.45% Sn, 3.5% Ag, and 0.-5% Cu) and the second solder alloy may be SACQ (e.g., 92.45% Sn, 4% Ag, 0.5% Cu, 3.0% Bi, and 0.05% Ni). However, other solder alloys, including other tin-silver-copper solder alloys, tin-bismuth solder alloys, or tin-bismuth-silver solder alloys, may be used.

A final ball alloy may be made up of an initial ball alloy (e.g., a BGA solder alloy) and a solder paste alloy that mixes with the initial ball alloy to create the final ball alloy. The initial ball alloy will make up a majority of a total alloy (e.g., 100% when a non-solder paste process is used), but approximately 15%-40% of the final ball alloy can be that of the solder paste alloy from a solder paste used. When looking to adjust solder alloys to various melting points, the solder paste alloy and volume of the solder paste alloy compared to a volume of the initial ball alloy may be considered. In other words, the solder alloys (e.g., the first solder alloy and the second solder alloy) may be made from a combination of the initial ball alloy and the solder paste alloy. The solder paste alloy may be used to adjust the melting point and/or the stiffness coefficient of the final ball alloy. In some cases, different solder paste alloys may be used in different regions of the BGA to alter a composition of the final ball alloy in those different regions. Therefore, the solder alloys described herein (e.g., the first solder alloy and the second solder alloy) may refer to the final ball alloy made from the combination of the initial ball alloy and the solder paste alloy.

In some implementations, a region of the substrate 110 (e.g., a region of the second substrate surface 155) that is located underneath (e.g., vertically overlapping with) a die edge of the first integrated circuit 105-1 or a die edge of the second integrated circuit 105-2 may be a high-stress area (e.g., a weak region). For example, a die may induce higher mechanical stresses onto the substrate 110 at a die edge than at an inner region of the die. Thus, a die (e.g., the first die 115-1) may have a die footprint defined by a plurality of die edges, and the second substrate surface 155 may have one or more high-stress areas corresponding to the plurality of die edges. In some cases, the high-stress areas corresponding to the plurality of die edges may surround a region (e.g., a low-stress area) that corresponds to an inner region of the die.

A solder ball that is located underneath a die edge in a high-stress area may be part of the first plurality of solder balls made of the first solder alloy. For example, the solder ball 140-3, located underneath a die edge of the first die 115-1, may be included in the first plurality of solder balls. Alternatively, the solder balls 140 located underneath one or more die edges may be part of a third plurality of solder balls made of a third solder alloy that is different from the first solder alloy and the second solder alloy. For example, the solder ball 140-3, located underneath the die edge of the first die 115-1, may be included in the third plurality of solder balls. The third solder alloy may have at least one of a higher melting point or a higher stiffness coefficient than the second solder alloy. In some cases, the third solder alloy may have at least one of a lower melting point or a lower stiffness coefficient than the first solder alloy.

In some cases, the solder ball 140-3 and the solder ball 140-8 may be considered to be at the die edges of the first die 115-1, and the solder balls 140-4 to 140-7 may be considered to be at an inner region of the first die 115-1. Thus, the second substrate surface 155 may include a die peripheral region that corresponds to (e.g., overlaps with) the plurality of die edges of the first die 115-1, and some of the solder balls of the first plurality of solder balls may be arranged in the die peripheral region that corresponds to the plurality of die edges of the first die 115-1. In contrast, the second plurality of solder balls may be located outside of (e.g., excluded from) the peripheral region 165 that corresponds to the edge region of the second substrate surface 155 and may be further located outside (e.g., excluded from) of the die peripheral region that corresponds to the plurality of die edges of the first die 115-1.

As a result of an arrangement of the first plurality of solder balls in high-stress areas and the second plurality of solder balls in low-stress areas, the warpage of the substrate 110 and/or the coplanarity of the solder balls 140 may be reduced, particularly during a reflow process. Thus, failures, such as solder joint failure, head-in-pillow defects, or ball breaks, may be reduced or prevented altogether. For example, two or more solder alloys in the multi-alloy BGA may be used and selectively arranged in order to counterbalance the warpage of the substrate 110 resulting from the mismatch in coefficients of thermal expansion between the substrate 110 and the casing 120, by inducing, for example, a mechanical stress in the substrate 110 that is counter to the mechanical stress induced by the casing 120. The two or more solder alloys in the multi-alloy BGA may be used and selectively arranged according to a warpage profile of the substrate 110 caused by the casing 120 (e.g., due to a mismatch in coefficients of thermal expansion between the substrate 110 and the casing 120).

As indicated above, FIG. 1 is provided as an example. Other examples may differ from what is described with regard to FIG. 1. The number and arrangement of components shown in FIG. 1 are provided as an example. In practice, there may be additional components, fewer components, different components, or differently arranged components than those shown in FIG. 1.

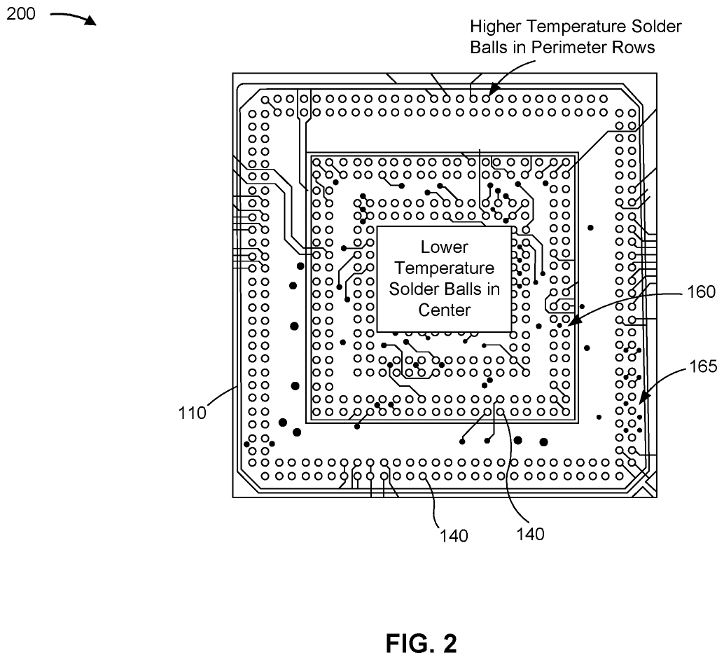

FIG. 2 is a diagram 200 of a ball side of a semiconductor package assembly according to one or more implementations. The semiconductor package assembly may be similar to semiconductor package assembly 145 described above in connection with FIG. 1. Thus, the second substrate surface 155 of the substrate 110 is illustrated in the diagram 200. The semiconductor package assembly includes the solder balls 140 (e.g., a plurality of conductive interconnect structures) arranged in a multi-alloy ball grid array on the second substrate surface 155. The second substrate surface 155 includes the inner region 160 in which the second plurality of solder balls made of the second solder alloy are arranged. In addition, the second substrate surface 155 includes the peripheral region 165 in which the first plurality of solder balls made of the first solder alloy are arranged. In some cases, one or more rows of solder balls may correspond to a die peripheral region that corresponds to (e.g., overlaps with) a plurality of die edges of a die (e.g., of the first die 115-1). The solder balls that are arranged in the correspond to the die peripheral region may also be made of the first solder alloy or a third solder alloy, as described above.

For example, a stiffer, stronger solder alloy may be placed in the corners and at a perimeter of the substrate 110, while interior balls may be made of a more ductile solder alloy to allow stress reduction under a die and a lower coefficient of thermal expansion (CTE) portion of the semiconductor package assembly 145. Thus, stiffer alloys may be placed in the peripheral region 165 for providing additional strength, and softer solder alloys may be placed in the inner region 160 for added ductility.

As indicated above, FIG. 2 is provided as an example. Other examples may differ from what is described with regard to FIG. 2.

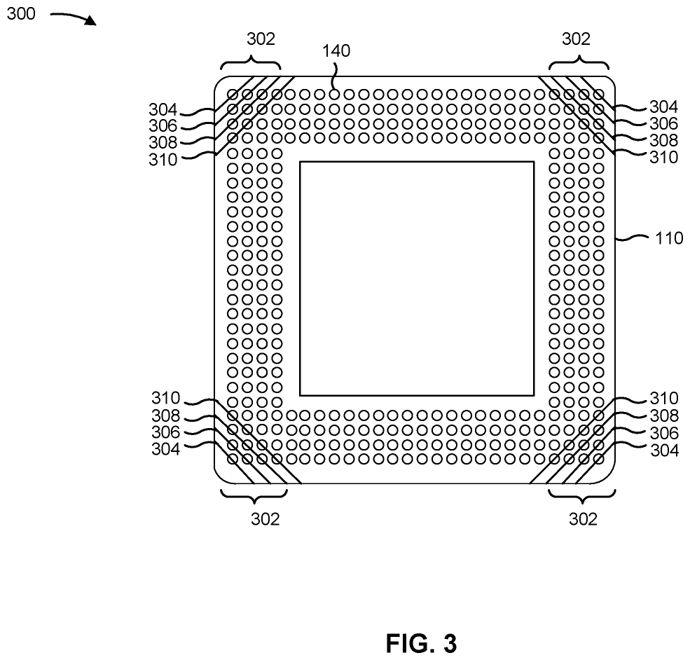

FIG. 3 is a diagram 300 of a ball side of a semiconductor package assembly according to one or more implementations. The second substrate surface 155 of the substrate 110 is illustrated in the diagram 300 and includes a multi-alloy BGA of solder balls 140. The substate 110 has four corners, each with a plurality of corner solder balls 302. The plurality of corner solder balls 302 may be arranged in diagonal rows 304, 306, and 308 that are diagonally displaced from a respective corner by a respective distance. A first diagonal row 304 may include a single solder ball. The second diagonal row 306 may include two solder balls. The third diagonal row 308 may include three solder balls. The solder balls 140 of the first diagonal row 304 and the second diagonal row 306 may be dummy solder balls or sacrificial solder balls that are not electrically coupled to any die. The solder balls 140 of the third diagonal row may each be electrically connected to at least one die (e.g., each may be a die-connected solder balls), or may include a mix of dummy solder balls and die-connected solder balls. The solder balls 140 of the first diagonal row 304 and the second diagonal row 306 may be configured to absorb most of the mechanical stress. If a corner ball breaks (e.g., the solder ball of the first diagonal row breaks), then the two solder balls of the second diagonal row 306 will share the mechanical stress. Thus, the solder balls 140 of the first diagonal row 304 and the second diagonal row 306 may be used to protect the die-connected solder balls of the third diagonal row 308 from breaking.

In some implementations, the solder balls 140 of the first diagonal row 304 and the second diagonal row 306 may be made or a solder alloy that is more ductile than a solder alloy used for the die-connected solder balls of the third diagonal row 308. The more ductile solder alloy may have a lower melting point than the less ductile solder alloy. The solder alloy used for the die-connected solder balls of the third diagonal row 308 may be used for the other solder balls 140 that are located in an inner region of the substrate 110. Alternatively, a different, less ductile solder alloy may be used for the remaining solder balls 140, including solder balls locating in a fourth diagonal row 310 and more inward diagonal rows, compared the solder alloy used for the solder balls of the third diagonal row 308.

Rather than most the mechanical forces being focused on a corner ball joint (e.g., on the solder balls 140 of the first diagonal row 304 and/or the second diagonal row 306), a ductility of the solder balls 140 of the first diagonal row 304 and the second diagonal row 306 may allow some “give” to the mechanical stresses. Thus, with a more ductile solder alloy used for the corner solder balls, the mechanical forces may be shared between more ductile solder balls at the corner and harder (less ductile) solder balls located towards a middle of the substrate 110, such as the solder balls of the third diagonal row 308 and other solder balls located further away from the corners. The lower

In some implementations, the ductility of a solder alloy may be gradually changed for each diagonal row 304, 306, and 308. For example, the solder ball of the first diagonal row 304 may be made of a first solder alloy having a first ductility, the solder balls of the second diagonal row 304 may be made of a second solder alloy having a second ductility that is less ductile and/or has a higher melting point then the first solder alloy, and the solder balls of the third diagonal row 308 may be made of a third solder alloy having a third ductility that is less ductile and/or has a higher melting point then the second solder alloy. In some implementations, the solder balls of the fourth diagonal row 310 and the solder balls located in an inner region of the substrate may be made of a fourth solder alloy having a fourth ductility that is less ductile and/or has a higher melting point then the third solder alloy. As a result, the mechanical forces may be spread out more evenly between the diagonal rows 304, 306, and 308, rather than being focused on the solder ball of the first diagonal row 304 (until the solder ball breaks). A ductility of the first solder alloy may be configured to match a strain on the second diagonal row 306. A ductility of the third solder alloy may be matched to a strain on the first diagonal row 304 and the second diagonal row 306.

As indicated above, FIG. 3 is provided as an example. Other examples may differ from what is described with regard to FIG. 3.

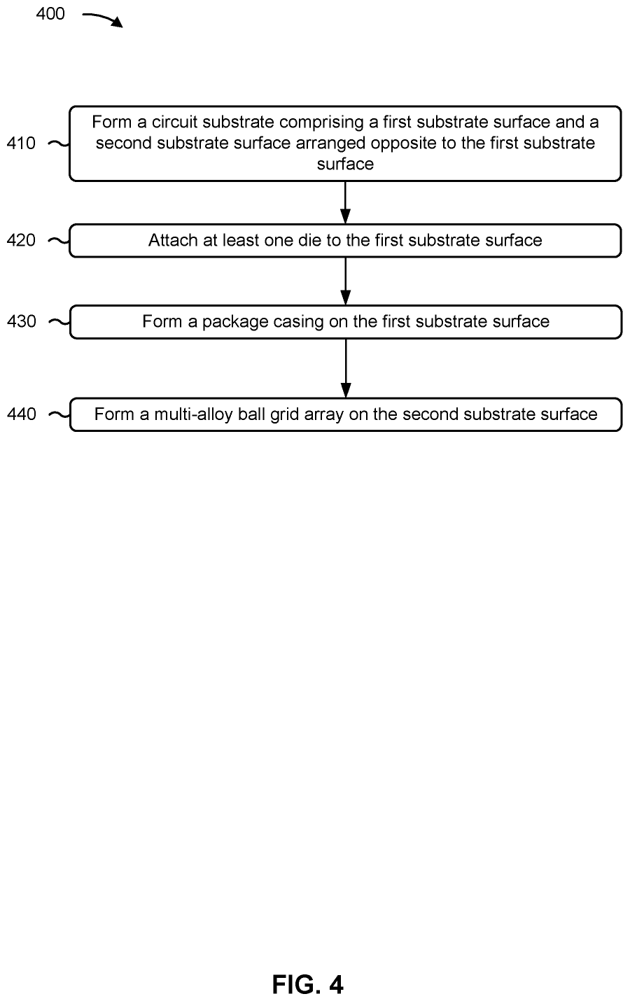

FIG. 4 is a flowchart of an example method 400 of forming a semiconductor device assembly or memory device having a multi-alloy ball grid array. In some implementations, one or more process blocks of FIG. 4 may be performed by various semiconductor manufacturing equipment.

As shown in FIG. 4, the method 400 may include forming a circuit substrate comprising a first substrate surface and a second substrate surface arranged opposite to the first substrate surface (block 410). As further shown in FIG. 4, the method 400 may include attaching at least one die to the first substrate surface (block 420). As further shown in FIG. 4, the method 400 may include forming a package casing on the first substrate surface (block 430). The package casing may encapsulate the at least one die and at least part of the first substrate surface. As further shown in FIG. 4, the method 400 may include forming a multi-alloy ball grid array on the second substrate surface (block 440). Forming the multi-alloy ball grid array on the second substrate surface may include forming a first plurality of solder balls made of a first solder alloy on the second substrate surface; and forming a second plurality of solder balls made of a second solder alloy on the second substrate surface, wherein the second solder alloy is different from the first solder alloy. The first plurality of solder balls and the second plurality of solder balls may be electrically coupled to the at least one die by the circuit substrate.

The method 400 may include additional aspects, such as any single aspect or any combination of aspects described below and/or in connection with one or more other methods described elsewhere herein.

In a first aspect, the method 400 includes identifying high-stress areas of the circuit substrate at which a mechanical stress of the circuit substrate satisfies a stress threshold, identifying low-stress areas of the circuit substrate at which the mechanical stress of the circuit substrate does not satisfy the stress threshold, depositing the first plurality of solder balls in the high-stress areas, and depositing the second plurality of solder balls in the low-stress areas.

In a second aspect, alone or in combination with the first aspect, a patterned arrangement of the first plurality of solder balls and the second plurality of solder balls is configured to reduce a coplanarity of the multi-alloy ball grid array.

In a third aspect, alone or in combination with one or more of the first and second aspects, a patterned arrangement of the first plurality of solder balls and the second plurality of solder balls is configured to reduce head-in-pillow defects.

In a fourth aspect, alone or in combination with one or more of the first through third aspects, the first solder alloy has at least one of a higher melting point or a higher stiffness coefficient than the second solder alloy.

In a fifth aspect, alone or in combination with one or more of the first through fourth aspects, the first solder alloy has a higher melting point than the second solder alloy, and forming the multi-alloy ball grid array includes a reflow process during which a difference in melting points between the first solder alloy and the second solder alloy causes the second plurality of solder balls to induce a surface tension on the second substrate surface that reduces a warpage of the circuit substrate such that the first plurality of solder balls remain in contact with a solder paste.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the semiconductor package assembly 145, an integrated assembly that includes the semiconductor package assembly 145, such as apparatus 100, any part described herein of the semiconductor package assembly 145, and/or any part described herein of an integrated assembly that includes the semiconductor package assembly 145. For example, the method 400 may include forming one or more of the parts 105, 110, 115, 120, 125, 130, 135, and/or 140.

In some implementations, a semiconductor device assembly includes a circuit substrate comprising a first substrate surface and a second substrate surface arranged opposite to the first substrate surface; at least one die arranged on the first substrate surface; a package casing disposed over the first substrate surface, wherein the package casing encapsulates the at least one die and covers at least part of the first substrate surface; and a multi-alloy ball grid array coupled to the second substrate surface, wherein the multi-alloy ball grid array includes a first plurality of solder balls made of a first solder alloy and a second plurality of solder balls made of a second solder alloy that is different from the first solder alloy.

In some implementations, a method of manufacturing a semiconductor device assembly includes forming a circuit substrate comprising a first substrate surface and a second substrate surface arranged opposite to the first substrate surface; attaching at least one die to the first substrate surface; forming a package casing on the first substrate surface, wherein the package casing encapsulates the at least one die and at least part of the first substrate surface; and forming a multi-alloy ball grid array on the second substrate surface, wherein forming the multi-alloy ball grid array on the second substrate surface comprises: forming a first plurality of solder balls made of a first solder alloy on the second substrate surface; and forming a second plurality of solder balls made of a second solder alloy on the second substrate surface, wherein the second solder alloy is different from the first solder alloy.

In some implementations, a ball grid array component package includes a circuit substrate comprising a first substrate surface and a second substrate surface arranged opposite to the first substrate surface, wherein the circuit substrate comprises a plurality of weak regions and a plurality of strong regions, wherein the plurality of weak regions is more susceptible to a failure than the plurality of strong regions; a die arranged on the first substrate surface; a package casing disposed over the first substrate surface, wherein the package casing encapsulates the die and covers at least part of the first substrate surface; and a multi-alloy ball grid array coupled to the second substrate surface, wherein the multi-alloy ball grid array includes a first plurality of solder balls made of a first solder alloy and a second plurality of solder balls made of a second solder alloy that is different from the first solder alloy, wherein the first plurality of solder balls and the second plurality of solder balls are electrically coupled to the die by the circuit substrate, wherein the first plurality of solder balls are arranged in the plurality of weak regions, wherein the second plurality of solder balls are arranged in the plurality of strong regions, and wherein the first solder alloy has at least one of a higher melting point or a higher stiffness coefficient than the second solder alloy.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a circuit substrate comprising a first substrate surface and a second substrate surface arranged opposite to the first substrate surface;
at least one die arranged on the first substrate surface;
a package casing disposed over the first substrate surface, wherein the package casing encapsulates the at least one die and covers at least part of the first substrate surface; and
a multi-alloy ball grid array coupled to the second substrate surface, wherein the multi-alloy ball grid array includes a first plurality of solder balls made of a first solder alloy and a second plurality of solder balls made of a second solder alloy that is different from the first solder alloy.

2. The semiconductor device assembly of claim 1, wherein the circuit substrate comprises high-stress areas at which a mechanical stress of the circuit substrate satisfies a stress threshold and low-stress areas at which the mechanical stress of the circuit substrate does not satisfy the stress threshold, and
wherein the first plurality of solder balls are arranged at the high-stress areas and the second plurality of solder balls are arranged at the low-stress areas.

3. The semiconductor device assembly of claim 2, wherein the first solder alloy has at least one of a higher melting point or a higher stiffness coefficient than the second solder alloy.

4. The semiconductor device assembly of claim 3, wherein a first melting point of the first solder alloy is at least 10% greater than a second melting point of the second solder alloy, or
wherein a first stiffness coefficient of the first solder alloy is at least 10% greater than a second stiffness coefficient of the second solder alloy.

5. The semiconductor device assembly of claim 2, wherein the first solder alloy is SACQ and the second solder alloy is SAC305.

6. The semiconductor device assembly of claim 2, wherein the second substrate surface comprises an inner region and a peripheral region that surrounds the inner region, and
wherein the first plurality of solder balls are arranged in the peripheral region and the second plurality of solder balls are arranged in the inner region.

7. The semiconductor device assembly of claim 6, wherein a total area of the second substrate surface is defined by a plurality of edges of the circuit substrate, and
wherein the peripheral region is adjacent to the plurality of edges of the circuit substrate.

8. The semiconductor device assembly of claim 1, wherein the at least one die includes a first die comprising a die footprint defined by a plurality of die edges,
wherein the second substrate surface comprises a peripheral region corresponding to the plurality of die edges, and
wherein the first plurality of solder balls are arranged in the peripheral region and the second plurality of solder balls are arranged outside of the peripheral region.

9. The semiconductor device assembly of claim 8, wherein the peripheral region overlaps with the plurality of die edges.

10. The semiconductor device assembly of claim 8, wherein the second substrate surface comprises an edge region, and
wherein the first plurality of solder balls are arranged in the edge region and the second plurality of solder balls are arranged outside of the edge region and outside of the peripheral region.

11. The semiconductor device assembly of claim 10, wherein the edge region encircles an inner region of the second substrate surface.

12. The semiconductor device assembly of claim 8, wherein the second plurality of solder balls includes at least one solder ball arranged on the second substrate surface opposite to the first die in an area surrounded by the peripheral region.

13. The semiconductor device assembly of claim 1, wherein the multi-alloy ball grid array includes a third plurality of solder balls made of a third solder alloy that is different from the first solder alloy and the second solder alloy.

14. A method of manufacturing a semiconductor device assembly, the method comprising:
forming a circuit substrate comprising a first substrate surface and a second substrate surface arranged opposite to the first substrate surface;
attaching at least one die to the first substrate surface;
forming a package casing on the first substrate surface, wherein the package casing encapsulates the at least one die and at least part of the first substrate surface; and
forming a multi-alloy ball grid array on the second substrate surface, wherein forming the multi-alloy ball grid array on the second substrate surface comprises:
forming a first plurality of solder balls made of a first solder alloy on the second substrate surface; and
forming a second plurality of solder balls made of a second solder alloy on the second substrate surface, wherein the second solder alloy is different from the first solder alloy.

15. The method of claim 14, further comprising:
identifying high-stress areas of the circuit substrate at which a mechanical stress of the circuit substrate satisfies a stress threshold;
identifying low-stress areas of the circuit substrate at which the mechanical stress of the circuit substrate does not satisfy the stress threshold;
depositing the first plurality of solder balls in the high-stress areas; and
depositing the second plurality of solder balls in the low-stress areas.

16. The method of claim 15, wherein a patterned arrangement of the first plurality of solder balls and the second plurality of solder balls is configured to reduce a coplanarity of the multi-alloy ball grid array.

17. The method of claim 15, wherein a patterned arrangement of the first plurality of solder balls and the second plurality of solder balls is configured to reduce head-in-pillow defects.

18. The method of claim 15, wherein the first solder alloy has at least one of a higher melting point or a higher stiffness coefficient than the second solder alloy.

19. The method of claim 15, wherein the first solder alloy has a higher melting point than the second solder alloy, and
wherein forming the multi-alloy ball grid array includes a reflow process during which a difference in melting points between the first solder alloy and the second solder alloy causes the second plurality of solder balls to induce a surface tension on the second substrate surface that reduces a warpage of the circuit substrate such that the first plurality of solder balls remain in contact with a solder paste.

20. A ball grid array component package, comprising:
a circuit substrate comprising a first substrate surface and a second substrate surface arranged opposite to the first substrate surface, wherein the circuit substrate comprises a plurality of weak regions and a plurality of strong regions, wherein the plurality of weak regions is more susceptible to a failure than the plurality of strong regions;
a die arranged on the first substrate surface;
a package casing disposed over the first substrate surface, wherein the package casing encapsulates the die and covers at least part of the first substrate surface; and
a multi-alloy ball grid array coupled to the second substrate surface,
wherein the multi-alloy ball grid array includes a first plurality of solder balls made of a first solder alloy and a second plurality of solder balls made of a second solder alloy that is different from the first solder alloy,
wherein the first plurality of solder balls and the second plurality of solder balls are electrically coupled to the die by the circuit substrate,
wherein the first plurality of solder balls are arranged in the plurality of weak regions,
wherein the second plurality of solder balls are arranged in the plurality of strong regions, and
wherein the first solder alloy has at least one of a higher melting point or a higher stiffness coefficient than the second solder alloy.
